(19) United States
(12) Patent Application Publication
(10) Pub. No.: US 2018/0012659 A1
(43) Pub. Date: Jan. 11, 2018

(54) Tunnel FET Based Non-Volatile Memory Boosted By Vertical Band-to-Band Tunneling

(71) Applicant: ECOLE POLYTECHNIQUE FEDERALE DE LAUSANNE (EPFL), Lausanne (CH)

(72) Inventors: Arnab Biswas, Munchen (DE); Saurabh Tomar, Echandens (CH); Adrian Mihai Ionescu, Ecublens (CH)

(21) Appl. No.: 15/641,472

(22) Filed: Jul. 5, 2017

Related U.S. Application Data
(60) Provisional application No. 62/358,202, filed on Jul. 5, 2016.

(51) Int. Cl. G11C 16/04; G11C 16/14; G11C 16/26; H01L 29/78

(52) U.S. Cl. CPC G11C 16/0466; H01L 29/78; G11C 16/14; G11C 16/26; H01L 27/11568

(57) ABSTRACT

A tunnel field effect transistor (TFET), including a source region, a gate region, a channel region, and a drain region, the gate region including a gate stack, wherein an area of the source region that is facing the channel region is overlapped by the gate stack.

### CROSS-REFERENCE TO RELATED APPLICATIONS

The present invention claims priority to the U.S. provisional patent application with the Ser. No. 62/358,202 that was filed on Jul. 5, 2016, the entire contents thereof being herewith incorporated by reference.

### FIELD OF THE INVENTION

The present invention relates to the field of Tunnel Field Effect Transistors (TFET), low voltage operation transistors, nanoscale transistors, and application of the same as non-volatile memory devices.

### BACKGROUND

Due to their mode of operation Tunnel Field Effect Transistors (TFETs) have been proposed in reference [2] as steep slope switches able to reduce the voltage operation of logic circuits below 0.2V with reduced leakage current and improved switching energy efficiency. While high-performance TFETs exploit InAs-Si hetero-structures on nanowires, as shown in reference [3], the all-Si homo-junction TFET family appears primarily to have a very high I_{ON}/I_{OFF} and the lowest I_{OFF} as shown in reference [4] yet fail to achieve the requirements of I_{ON}. Due to its excellent reliability, charge-trapping silicon oxide-nitride-oxide-silicon (SONOS) NVM is a promising alternative to conventional floating-gate flash devices at the next 16-nm technology node, as shown in reference [5].

While reference [6] proposed a non-volatile memory with a TFET, they have used a conventional lateral tunneling nano-wire with limited performance of the TFET device and an oxide-nitride-oxide (ONO) stack. In a Tunnel FET the gate modulation of tunneling barrier is of great significance. In a conventional lateral TFET, the carriers tunneling from source to the channel are not aligned to the gate electric field which id vertical. Accordingly, only a part of the gate field is utilized in band to band tunneling of carriers. Thus it becomes evident that in order to have a better gate modulation in a TFET, the tunneling direction should be aligned to the gate electric field. Such TFETs, called “Line Tunneling” have their source region significantly overlapped by the gate as shown in reference [1]. It leads to optimal control of the carrier injection mechanism and results in the best modulation on the drain current levels. In such device architectures, the band-to-band (BTB) tunneling takes place from an inversion layer induced in the source by the gate field [1]. Such devices show much better sub threshold slope than lateral devices over a large gate voltage range.

An ideal optimized Tunnel FET structure is simulated with ONO stack to simulate its memory operation and compared with MOSFET based nonvolatile memory, as shown in reference [7]. We then demonstrate the nonvolatile memory operation on a simplified Tunnel FET architecture by fabricating it with a high-k Al₂O₃/HfO₂/Al₂O₃ gate stack and experimentally show how vertical tunneling boosts the memory operation in NVM cells, as shown in reference [8].

However, despite all these advancements and improvements in the field of Tunnel FET, advanced devices are desired, specifically to improve upon the characteristics for non-volatile memory operation, for example to increase trapped charges for memory operation, and to better control the carrier injection. Therefore, novel Tunnel FET devices with substantially improved characteristics are desired.

### SUMMARY

According to one aspect of the present invention, a tunnel field effect transistor (TFET) is provided, including a source region, a gate region, a channel region, and a drain region, the gate region including a gate stack. Moreover, an area of the source region that is facing the channel region is overlapped by the gate stack.

According to another aspect of the present invention, a method for operating a tunnel field effect transistor in a non-volatile memory device is provided. Preferably, the tunnel field effect transistor includes a source region, a gate region, a channel region, and a drain region, the gate region including a gate stack, wherein an area of the source region that is facing the channel region is overlapped by the gate stack. In addition, preferably the method includes the steps of performing a write operation, performing a read operation, and performing an erase operation.

According to yet another aspect of the present invention, a method for operating a tunnel field effect transistor in a non-volatile memory device is provided. Preferably, the tunnel field effect transistor includes a source region, a gate region, a channel region, a drain region, and a substrate, the gate region including a gate stack, wherein an area of the source region that is facing the channel region is overlapped by the gate stack. Moreover, the method preferably includes the step of operating the tunnel field effect transistor using vertical band-to-band tunneling to augment charge trapping in the gate stack.

According to still another aspect of the present invention, a vertical band-to-band tunneling operation is used due to the specific architecture of the Tunnel FET that allows to boost the charge storage in gate stack, as compared to the background art non-volatile MOSFET memories and background art lateral Tunnel FET memories, and offers stability at elevated temperatures.

The above and other objects, features and advantages of the present invention and the manner of realizing them will become more apparent, and the invention itself will best be understood from a study of the following description with reference to the attached drawings showing some preferred embodiments of the invention.

### BRIEF DESCRIPTION OF THE SEVERAL VIEWS OF THE DRAWINGS AND TABLES

The accompanying drawings, which are incorporated herein and constitute part of this specification, illustrate the presently preferred embodiments of the invention, and together with the general description and the tables given above and the detailed description given below, serve to explain features of the invention.

FIG. 1 shows cross-sectional schematic view of the simulated device with oxide-nitride-oxide (ONO) gate stack;

FIG. 2 shows a schematic representation of the energy band diagram of charge storing gate stack for a p-type memory device;

FIG. 3A shows a graph representing trapped electron and hole charge in nitride region of the memory;

FIG. 3B shows a graph representing hole barrier-tunneling generation a function of time during the programmed erase cycles;

FIG. 3C shows a graph representing I_{D}-V_{G} curves for program and erase states for both n & p type vertical TFET and MOSFET non-volatile memory;

FIG. 4 shows Technology Computer-Aided Design (TCAD) simulation result showing in (bottom) the electron band-to-band generation at the end of the programming step and (top) the trapped electron concentration close to the interface between the tunneling oxide and the charge trapping layer, in a cross-sectional view of an exemplary device;

FIGS. 5A and 5B show schematics of the top view in FIG. 5A and cross sectional view in FIG. 5B, respectively. The dimensions of the exemplary nonvolatile memory device are L_{g}=15 μm, LOV=12 μm, W_{g}=5 μm, tₛᵢ=20 nm, Al2O3/HfO2/Al2O3/Si=15 nm/10 nm/7 nm/30 nm;

FIG. 6 shows a scanning electron microscope (SEM) image of the top view of an exemplary nonvolatile memory device fabricated;

FIGS. 7A and 7B show cross sectional views of the simulated device, with the high-k gate stack, showing hole BTB generation and FN injection in FIG. 7A and a hole BTB (vertical) tunneling current density in FIG. 7B;

FIG. 8 shows the energy band diagram of the proposed vertical TFET NVM device along y-axis. The TCAD simulated plot shows the magnitude and location of the hole BTB generated carriers which tunnel to the charge trap stack;

FIG. 9 shows graphs that represent initial, program and erase transfer curves after −15V programming pulse with 10 μs width and then an erase pulse of +15V of 10 μs duration;

FIG. 10 shows a graph that represent the I_{ON} of the device scaling linearly with overlap area of source gated region(L_{OV}), where the vertical tunneling takes place;

FIG. 11 shows a graph representing the effect of the gate voltage range sweeps on the hysteresis;

FIG. 12 shows a graph representing hysteresis transfer curves after up to 10⁶ program-erase cycles;

FIG. 13 shows a graph representing hysteresis transfer curves with increasing programming pulse width;

FIG. 14 shows a graph representing highly stable hysteresis transfer curves with increasing temperature;

FIG. 15 shows a graph representing highly stable hysteresis transfer curves with increasing temperature from 77K to 400K. Inset shows the gate leakage over a function of temperature;

FIGS. 16A to 16C shows graphs representing threshold voltage, VT, with FIG. 16A versus number of pulses for program/erase, FIG. 16B with different programming pulse widths for program/erase, and FIG. 16C with memory window stability with increasing temperature up to 400K;

FIG. 17 shows a graph representing measured retention time at room temperature for a 10 μsec programming;

Table I shows a summary of relevant patents and publications of non-volatile memory devices;

Table II shows non-volatile memory (NVM) parameter comparison of recent devices;

Table III lists the parameters of the device that has been simulated; and

Table IV shows the programming scheme for a p-type device.

Herein, identical reference numerals are used, where possible, to designate identical elements that are common to the figures. Also, the images are simplified for illustration purposes and may not be depicted to scale.

### BRIEF DESCRIPTION OF THE SEVERAL EMBODIMENTS

A nonvolatile memory device using Tunnel Field Effect Transistor (TFET) rather than conventional Metal-Oxide-Semiconductor Field Effect Transistor (MOSFET) is provided. The nonvolatile memory device is realized using a unique architecture, with source of the device underlapping the gate of the Tunnel FET resulting in the alignment of the gate electric field to both the Fowler-Nordheim (FN) tunneling field and the Band-to-Band (BTB) tunneling direction. This field alignment results in the generation of BTB carriers just under the gate oxide in addition to the inversion carriers and thus provides enhanced charge injection into the used high-K oxides charge trapping gate stack.

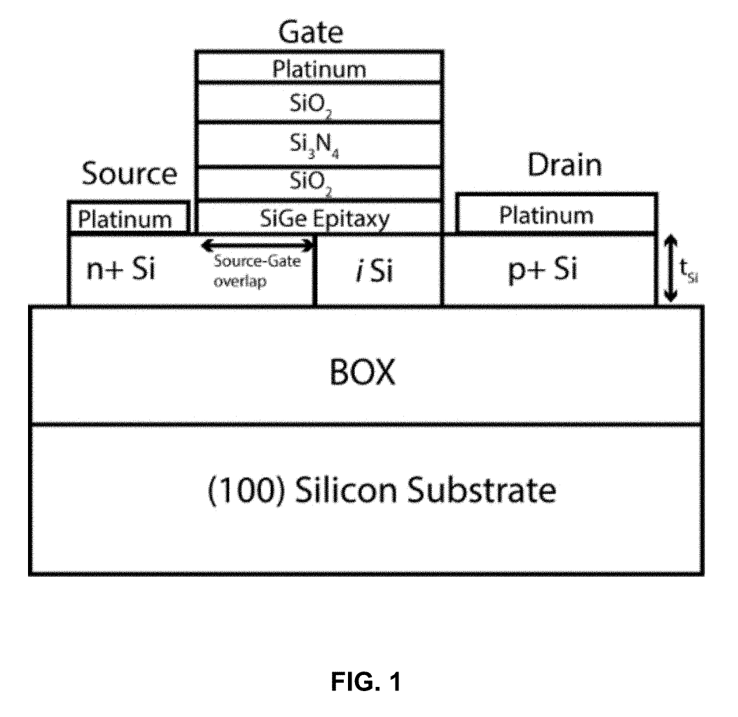

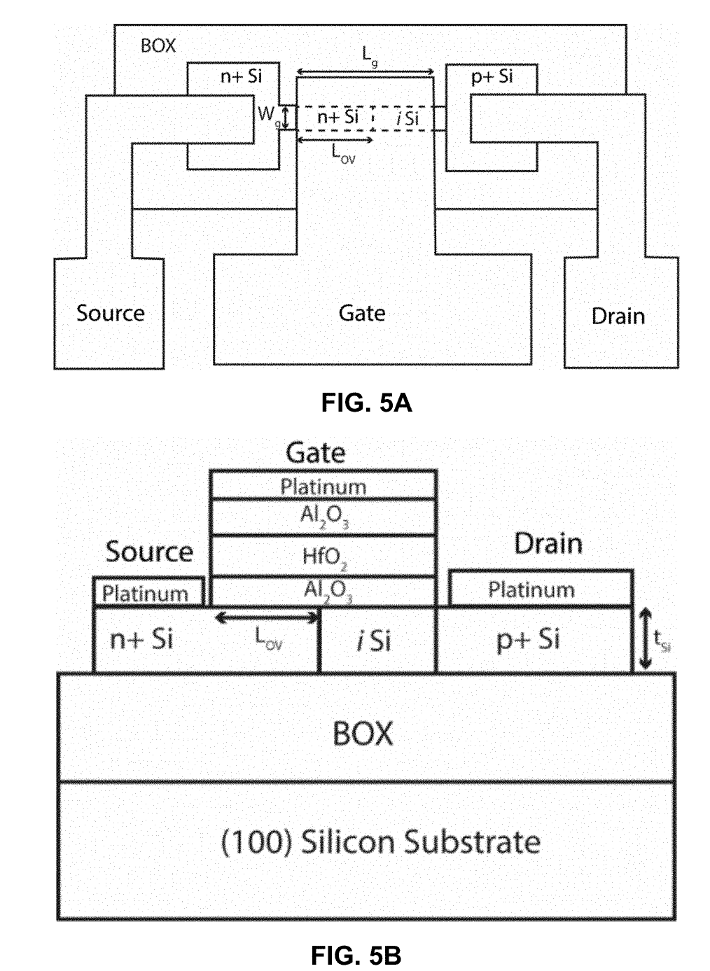

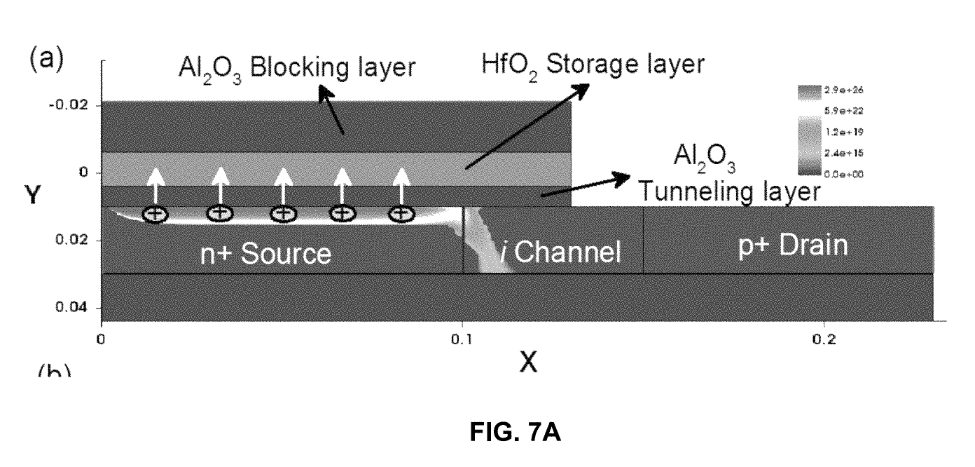

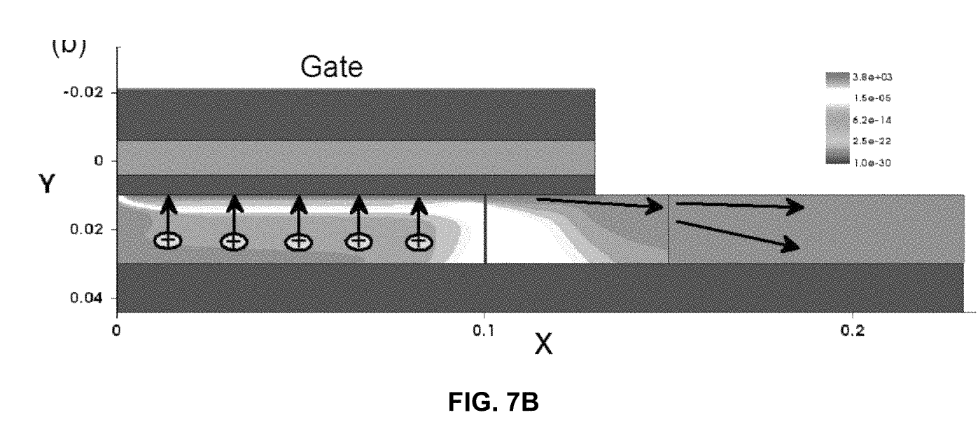

As shown in FIG. 1, an exemplary embodiment of the Tunnel FET is provided that includes a source electrode made of conductive material such as platinum that contacts the source region made of highly doped n-type Si, a gate electrode made of a conductive material such as platinum that contacts a gate stack, the gate stack having charge-trapping capabilities, in the variant shown to be made from three (3) layers. Next, an epitaxy layer that is arranged under the gate stack, made of SiGe, an upper surface of the epitaxy layer being in contact with the gate stack, and the lower surface of the epitaxy layer being in contact with both i) the source region, along a length L_{OV} forming the source-gate overlap region, and ii) the channel region i Si. Next, a drain electrode is arranged made of a conductive material such as platinum that contacts the drain region made of highly doped p-type Si. A channel region i Si is arranged laterally between the source region and the drain region, and the upper surface of channel region i Si being in contact with epitaxial layer. Source region, channel region, and drain region are arranged on top of a buried oxide layer (BOX), that in turn is formed on top of a (100) silicon substrate. In a variant, no epitaxy layer that is arranged between the gate stack and the channel region/source region, and the lower surface of gate stack is in contact with both the source region in the source-gate overlap region and channel region, as shown in FIG. 5B. Also, in the variant shown, the epitaxial layer appears to cover the entire upper surface of the channel region, however, it is also possible that only a part of the channel layer is covered by the epitaxial layer/gate stack, as shown in FIG. 7A.

Next, the principle of the Tunnel FET memory operation is explained. The memory operation is based on the generation of band-to-band carriers just under the gate oxide stack. These carriers are available for tunneling right under the gate stack. When a suitable program/erase voltage is applied on the gate these carriers either tunnel into or out of the charge trap layer through tunneling oxide. Because the tunneling direction is now aligned to the component of the electric field modulated by the gate, this device offers good control of the carrier injection mechanism and a strong modulation on the drain current levels, as shown in reference

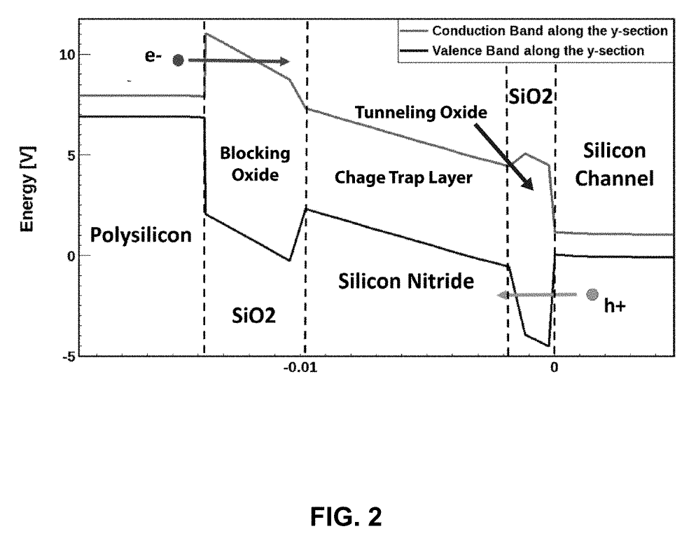

Choice of suitable oxide stack is critical for non volatile memory operation. The tunneling oxide should be thin enough to allow Fowler-Nordheim (FN) tunneling of BTB carriers into the gate stack on application of suitable program/erase voltage at gate stack. Similarly, the blocking oxide should be thick enough to prevent carrier injection from the gate into the gate stack throughout the program/erase voltage range. The charge trap layer should have appropriate conduction and valence band offset with respect to the tunneling oxide and blocking oxide so that it facilitates charge storage in the charge trap layer. FIG. 2 illustrates the gate stack using oxide-nitride-oxide gate stack example. The charge trapping gate stack can also be realized using high-K oxides if they satisfy the band offset conditions. It has been reported that high-K materials offer better alternatives to silicon nitrides for charge trapping below 4nm of charge trap oxide thickness, see for example references [5], [11].

According to one aspect, the Tunnel FET device is a p-type device due to its doping scheme and hence the programming scheme of the memory is such that the programming voltage is Vₚ=−9V and the erase voltage is V_{E}=8V, as shown in Table IV. During the programming phase, electrons are trapped inside the nitride layer instead of holes and the programmed ID-V_{g} (Drain current vs gate voltage) curve is shifted towards low negative gate voltages.

Next, the TCAD simulation of the memory operation of the proposed Tunnel FET is explained, according to an aspect of the present invention. The proposed memory operation is simulated with Sentaurus™ TCAD on a gated p+/i/n+ (highly doped p-type/insulator/highly doped n-type) structure, as exemplarily illustrated in FIG. 1, and the parameters of the simulated device are represented in Table III.

The SONOS structure and the TFET-based non-volatile memory have been created using Sentaurus™ Structure Editor. In both cases the gate stack consists of a 1.8 nm SiO2 layer, an 8.0 nm Si3N4 layer, and a 4.0 nm SiO2 layer between the channel area and the poly-silicon gate. In the case of the TFET-based structure the silicon substrate has been substituted with a thick buried oxide layer and a 20 nm thick silicon epitaxial layer (SOI TFET) in order to avoid perturbations to the TFET current levels because of the substrate contact. Source and drain in the MOS based structure are doped with a Gaussian profile of Arsenic (10²⁰ cm⁻³), while the substrate is doped uniformly with boron (10¹⁶ cm⁻³). In case of the TFET, the source doping was kept at 10²⁰ cm⁻³, the channel area and the SiGe (Silicon-Germanium with 30% Germanium) part as kept undoped (10¹⁵ cm⁻³,) and the drain was lowly doped at 10¹⁹ cm⁻³. The choice of a lower drain doping is needed to reduce the unwanted ambipolar behavior of TFET.

Sentaurus Device is also used to simulate the program and erase cycle of both the devices and to simulate the ID-VG curves during the read cycle. The single programming cycle is composed of a write phase, a hold phase of 2.5 msec, an erase phase and an hold phase of 5 msec. In the write phase for a p-type device a voltage of 9 V is applied to the gate contact for 0.5 msec, in the erase phase a voltage of −8 V is applied for 7.5 msec and in the hold phases no voltage is applied. The programming voltages of a n-type device will be of opposite polarity. The programming scheme for a p-type device is also shown in Table IV.

The program and erase operations were conducted within a single transient simulation by varying the gate voltage, then the final program and erase states are saved at the end of a series of programming cycles to obtain the steady-state solution. In order to facilitate the convergence of the simulation, especially in case of the TFET-based memory, the meshing strategy in the gate stack has been designed to result in a high-quality mesh without excessive node counts. The rest of the meshing strategy has been defined using regular refinement boxes, which specify the allowed minimum and maximum mesh spacing within a specified area. For more details on the simulation models used refer to the example project in Sentaurus Workbench SONOS Memory by Synopsys™, TCAD user guide Ver: I 2014.09.

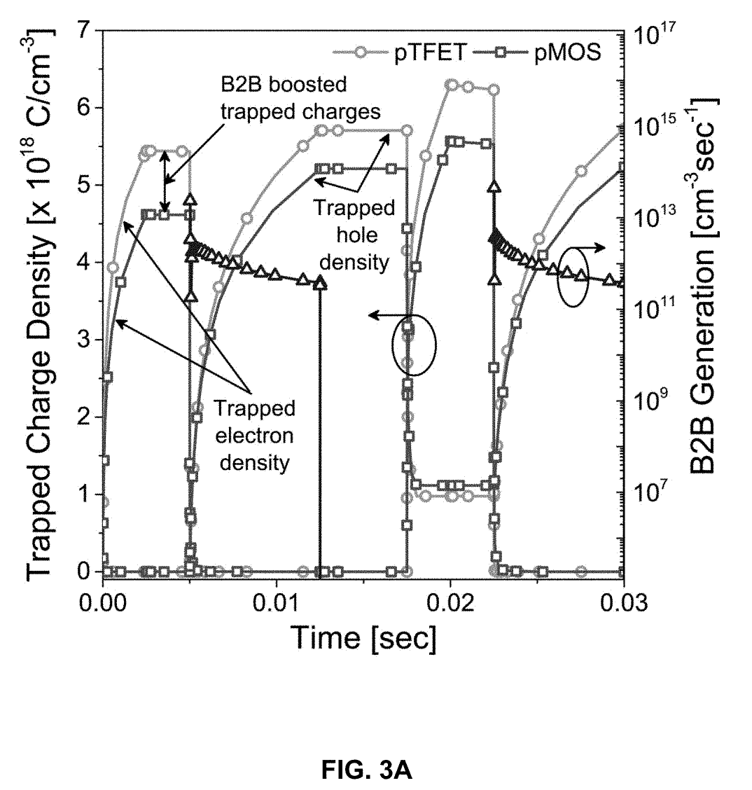

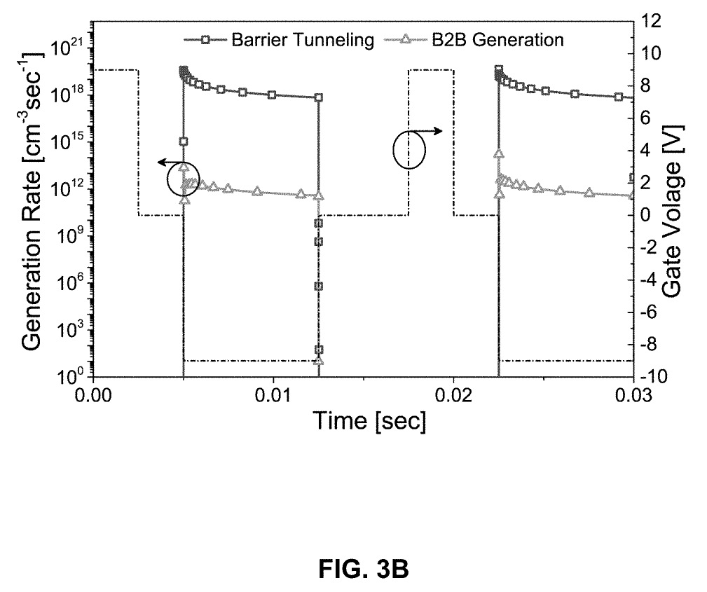

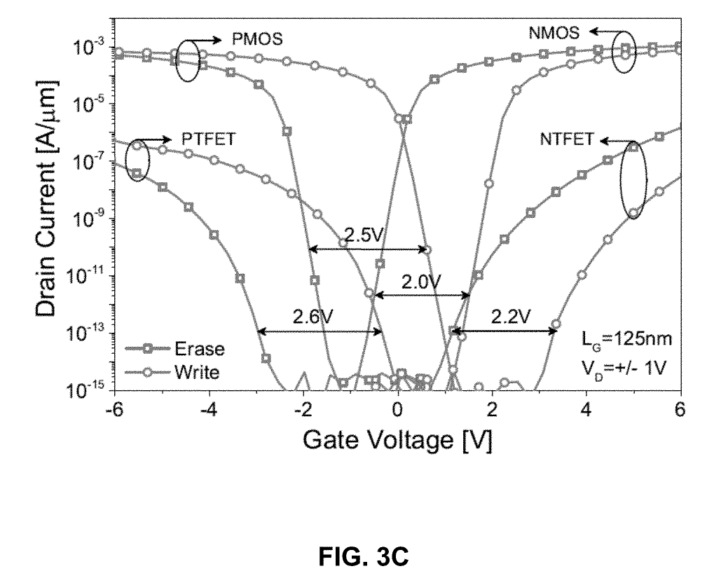

The simulation of two programming cycles for a p-type TFET as shown in FIG. 1 as well as a conventional p-type (Metal-Oxide-Semiconductor) MOS transistor of same dimensions and specifications are shown in FIGS. 3A to 3C.

It is interesting to notice, as shown in FIG. 3A, that the increased hole trapped charges in the nitride layer for the case of p-type TFET at the same programming voltage, is due to the carrier generation boost by band-to-band tunneling generation and alignment of gate electric field to the direction of tunneling into the stack. Such phenomenon is absent in conventional MOSFET based design. Generally speaking, the gate-source overlap architecture of the Tunnel FET device offers superior carrier generation and charge injection into the gate stack at a given voltage as compared to MOSFETs, thus enabling efficient memory operation. In FIG. 3B, the graphs show how the hole band-to-band tunneling generation is boosting the total number of holes injected in the trapping layer. The total barrier tunneling is following the trend of band to band generation of the carriers. Thus reaffirming again, the fact that band to band carrier generation is increasing the number of carriers stored in the nitride layer, resulting in larger threshold voltage (V_{T}) shift. From the graphs shown in FIG. 3C, it can be seen that the performances of the vertical tunneling device are substantially improved over the background art lateral TFET-based memory devices. Thanks to the vertical architecture enhanced with the hetero-structure Si/SiGe, the saturation current is increased of more than three orders of magnitude: the horizontal TFET allowed a saturation current ION≧10-10 A, the vertical presents ION≧10-7 A. The bigger number of trapped holes due to the band-to-band-tunneling generation (boosting effect) cause a threshold voltage shift of 2.6V, which is higher of the corresponding value (2V) for the traditional MOSFET based SONOS flash memory.

This increased trapped charges ultimately translates into a bigger memory window, when the memory cell is read after a write or erase operation. When the gate voltage is swept from 0 V to +8(−9) V, the two curves present a spike which is due the opening of a wide B2B tunneling window at the source/channel interface. The large number of electrons (holes), generated in the SiGe via band-to-band tunneling, is available to tunnel through the bottom oxide into the nitride layer. As soon as the concentration of trapped electrons (holes) increases, the negative (positive) charges inside the nitride layer has the effect of screening the positive (negative) voltage applied to the gate contact and consequently reduces the tunneling window both at the source/channel interface and at the channel/bottom oxide interface. This explains the decreasing trend for both the barrier tunneling curves even if the gate voltage is fixed at +9(−8) V.

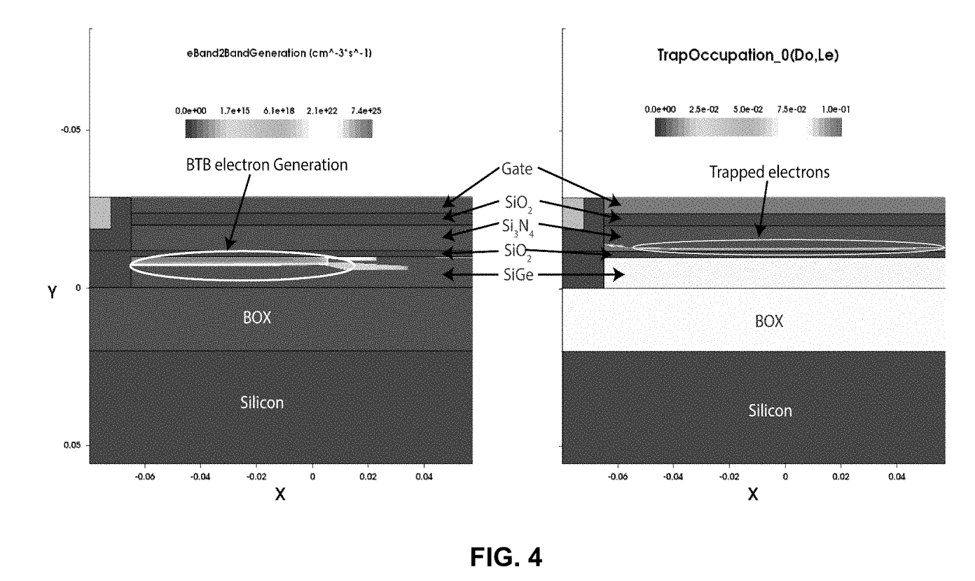

During the reading phase, the gate bias is swept from zero 0 V to +(−) 6 V for n(p)-type, the source is grounded and the drain is fixed at +(−)1.0 V. The I_{D}-V_{G} curves of program and erase states are plotted in FIG. 4. Thanks to the vertical architecture enhanced with the hetero-structure Si/SiGe, the saturation current I_{ON}>10⁻⁷ A. It is important to notice that the MOSFET structure is characterized by a saturation I_{ON}>10⁻⁵ A.

The most significant result is that the modified programming scheme and the bigger number of trapped holes due to the band-to-band-tunneling generation (boosting effect) cause a threshold voltage shift of 2.6V, which is higher of the corresponding value (2V) for the traditional MOSFET based SONOS flash memory.

FIG. 4 shows a simulation for n-type memory operation. On the left side of FIG. 4, it can be seen that the band-to-band generated electrons at the end of the programming state is just close to the tunneling oxide and hence can easily tunnel through. Also it can be seen on the right side in FIG. 4, how the trapped charges are more in concentration where the band-to-band generation is higher, clearly showing that the BTB generated carriers are boosting the memory operation.

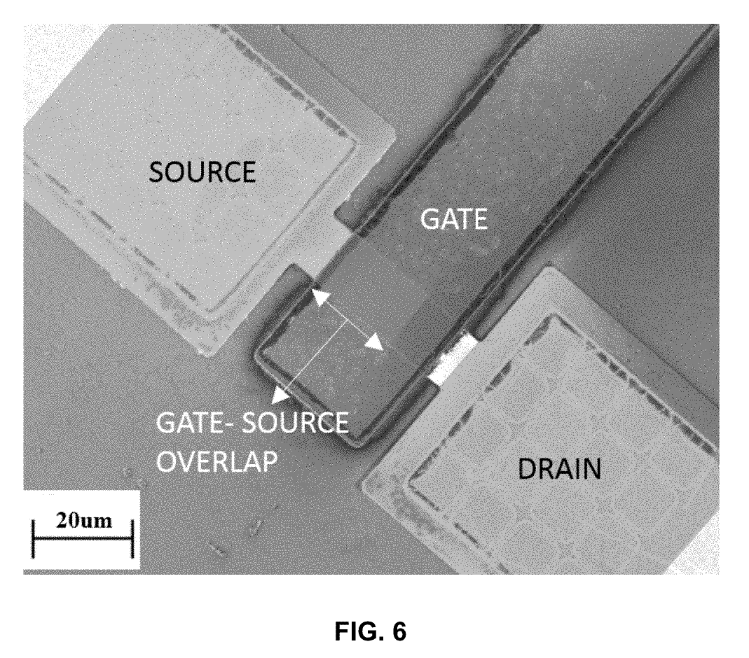

Next, experimental results of non-volatile memory device are discussed. A device was fabricated without the epitaxial SiGe layer, as shown in the simulated design of FIG. 1, and still demonstrated better memory characteristics than conventional devices, for example the one shown in reference [9]. Growing epitaxial layers on highly implanted thin Silicon on Insulator (SOI) is difficult. Thus, according to one aspect of the present invention, a device similar to FIG. 1 was manufactured, but without SiGe epitaxial layer to demonstrate the concept of vertical tunneling based non-volatile memory. FIG. 5A schematically shows the top view, and FIG. 5B schematically shows a cross-sectional of the fabricated device, according to one aspect of the present invention. FIG. 6 shows the Scanning Electron Microscope (SEM) image of fabricated device, showing the source-gate underlap.

Such vertical devices without epitaxial layer have been demonstrated and predicted to have good characteristics, for example as discussed in reference [10]. In the fabricated device, with architectures as shown in FIGS. 5A and 5B, the band-to-band(BTB) tunneling takes place from an inversion layer induced in the source by the gate field, as further shown in FIGS. 7A and 7B. Such devices show much better sub-threshold slope than lateral devices over a large gate voltage range.

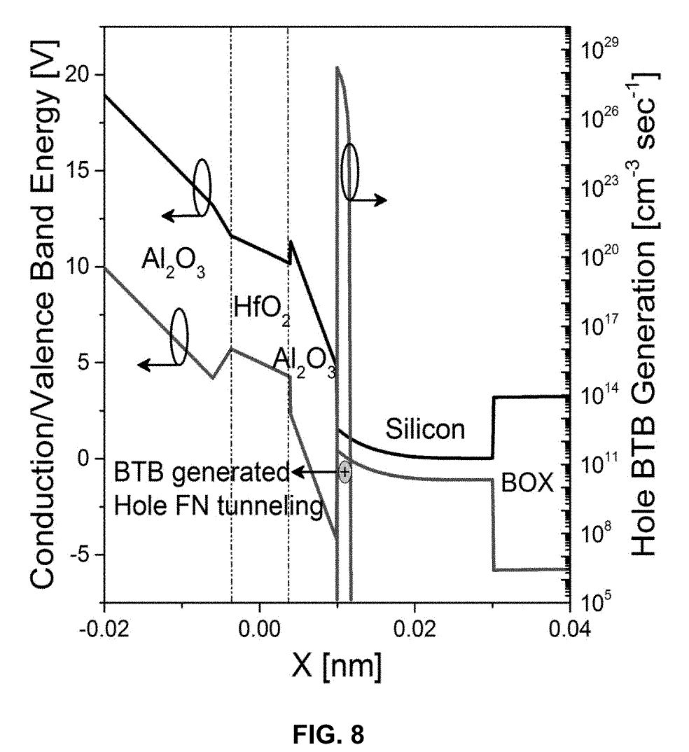

As shown in FIG. 8, the BTB generated carriers (holes) are very close to the high-k gate stack-silicon channel interface so that they can undergo Fowler-Nordheim (FN) tunneling into the NVM gate stack, thereby enhancing operation of this architecture as a memory cell as compared to background lateral devices.

The absence of a low band gap epitaxial layer above the source does affects the device working in certain way. Devices with low bandgap SiGe epitaxial layer are advantageous over the devices with just source-gate overlap, see FIGS. 5A and 5B. It is much easier to invert the intrinsic SiGe layer than a highly doped source. Thus BTB carrier generation happens at much lower gate voltage than that in just source-gate overlap. SiGe layer have lower band gap, depending upon the concentration of Germanium in SiGe, than just silicon. Thus in Tunnel FET they provide higher ON current (I_{ON}). The device shown in FIG. 1 is an improvement over the device in FIGS. 5A and 5B but both make use of vertical tunneling of BTB generated carriers to boost nonvolatile memory operation.

In accordance with another aspect of the present invention, with respect to the programming scheme or method, the following sequence can be used. (i) WRITE—The writing operations on the fabricated device was carried out by applying a pulse of −15V the at the gate for 10 μs, with drain, source and substrate all grounded. (ii) READ—The read operation was carried out at gate bias of −2V and drain voltage at −2V with source and substrate grounded. (iii) ERASE—The erase operation was carried out by applying a pulse of +15V at the gate for 10 μs, with drain, source and substrate all grounded. The WRITE cycle includes essentially the application of very high inverting voltage at the gate electrode, that leads to charge inversion in the channel, negative in case of p-type TFET, leading to tunneling of carriers into the charge trapping layer (HfO2) through the tunneling oxide (thinner Al2O3) from the underlapping highly doped source region or from the intrinsic Silicon-Germanium channel in case of device with SiGe epitaxy. In READ cycle we apply sufficient inverting voltage at the gate so that the device turns on but there is no carrier tunneling into the gate stack, thus the effect of WRITE/ERASE operations can be investigated by measuring this drain current. The ERASE cycle includes an application of high non inverting voltage such that it leads to tunneling of carriers into the charge trap layer just like in WRITE cycle but the carriers are of opposite polarity, thus they neutralize the previous stored charge during WRITE cycle.

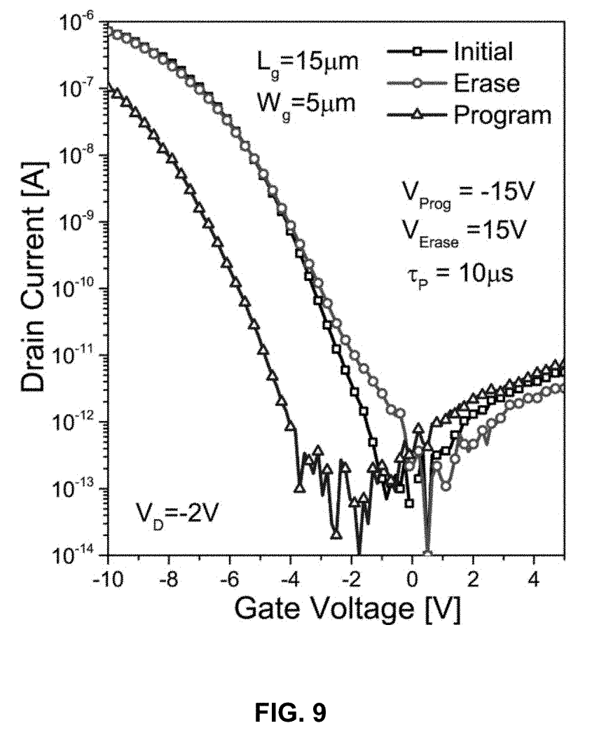

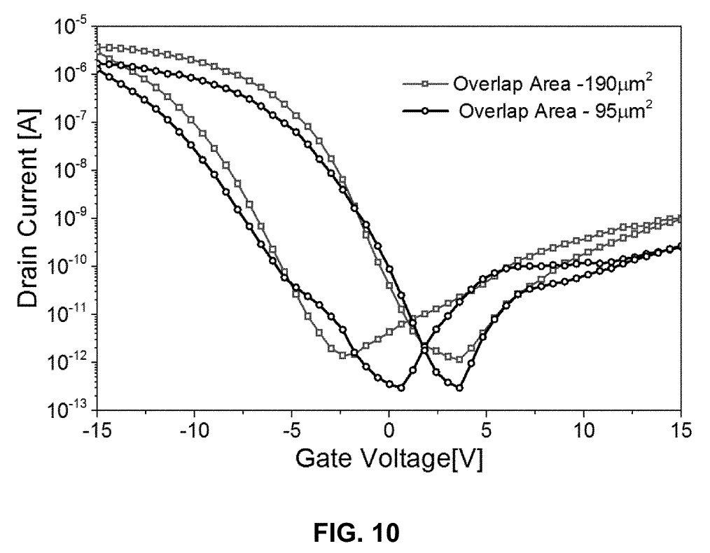

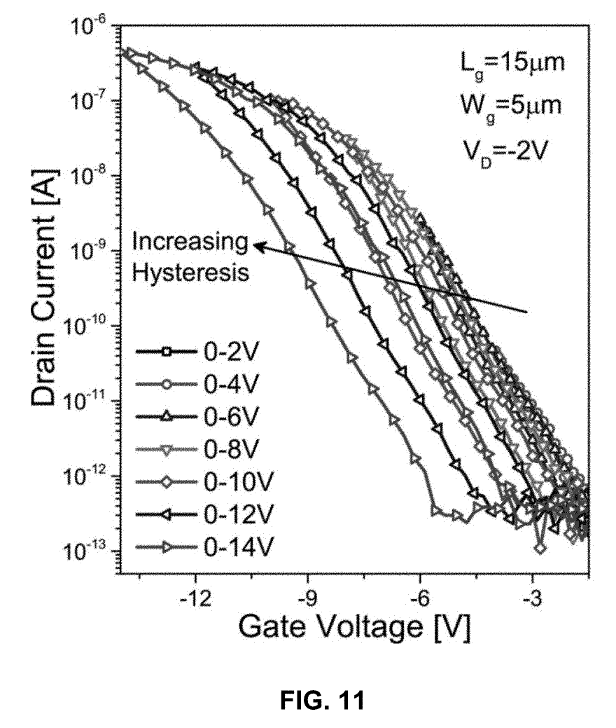

Next, a NVM memory characterization is provided. Extensive DC and transient characterizations were performed on the fabricated NVM TFETs, showing well behaved TFETs with low I_{off} current (<1 pA/μm). FIG. 9 shows the NVM operation of the fabricated device of FIGS. 5A and 5B depicting program/erase behavior with a −15V, 10 μs, programming pulse, showing drain current versus gate voltage. The memory reliably relaxes back to its initial state after an erase operation. FIG. 10 shows the dependence of ON current on the area of overlap of source with the gate, showing drain current versus gate voltage. The ON current scales with the overlap area. With twice increase in the overlap area, the ON current increases from 1.3 μA to 3.03 μA, showing that ON current depend on the overlapped tunneling area. FIG. 11 shows the effect of gate voltage sweep on memory window. As higher magnitude of V_{g}, the gate voltage, is applied at the gate, greater number of charge carriers tunnel though Al₂O₃ tunneling oxide, indicated by the increasing hysteresis. Thus increasing amount of charge injection/trapping occurs in HfO₂ charge trap layer leading to larger threshold voltage (V_{T}) shift.

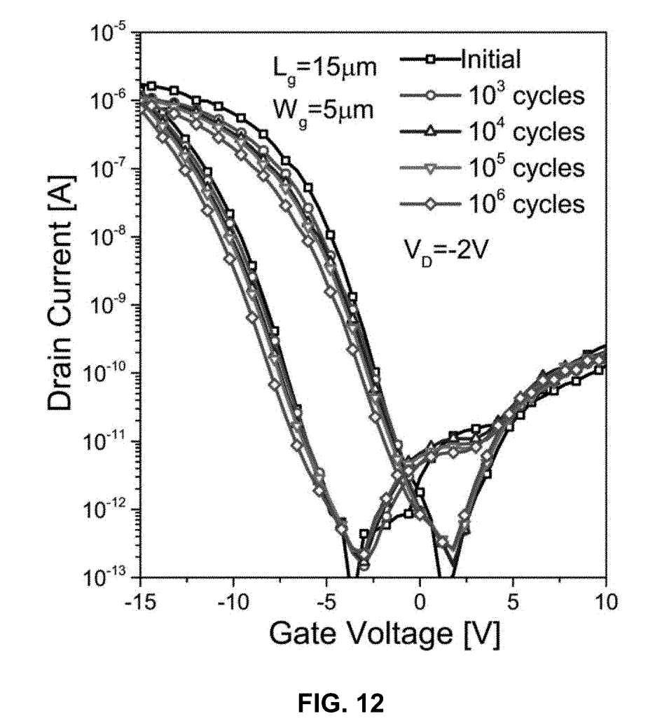

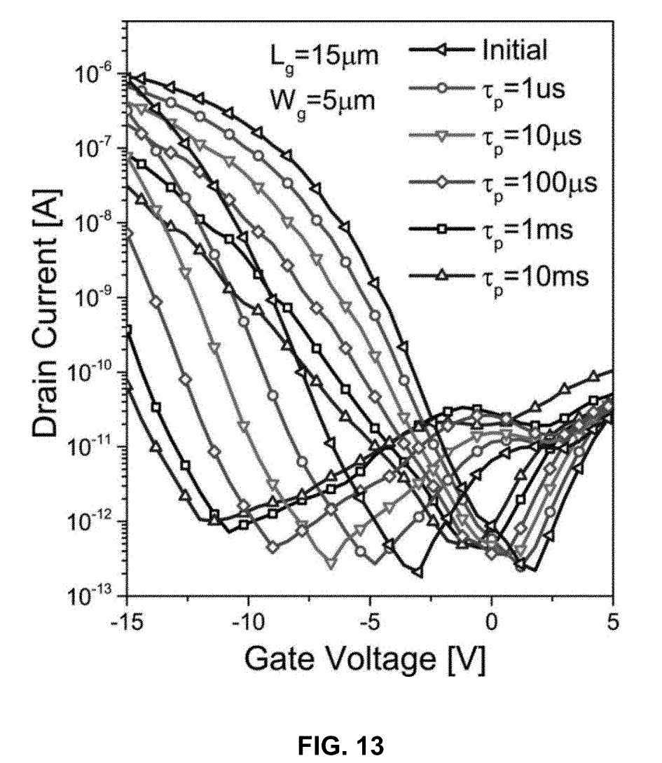

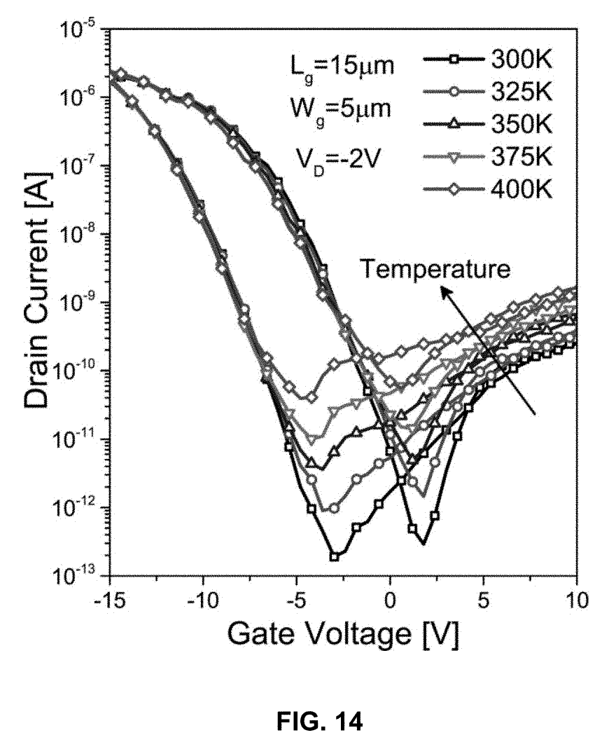

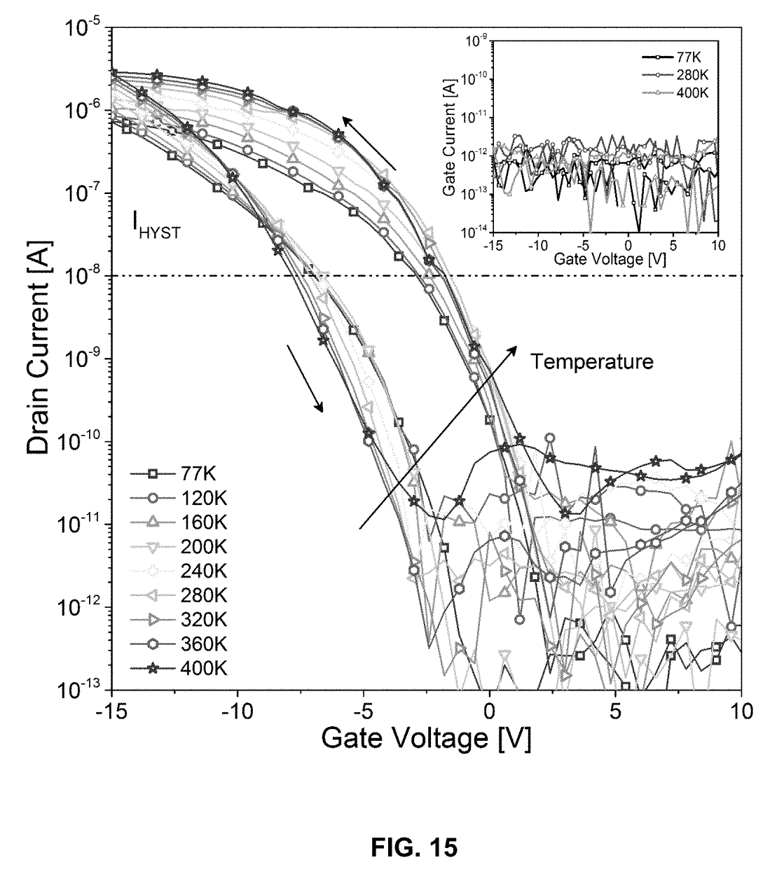

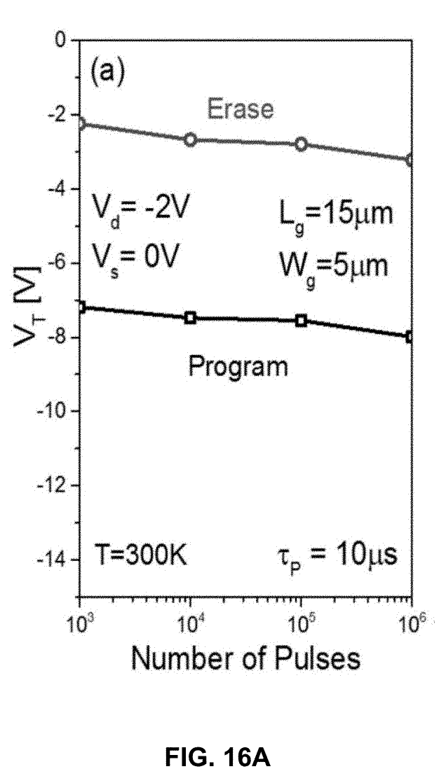

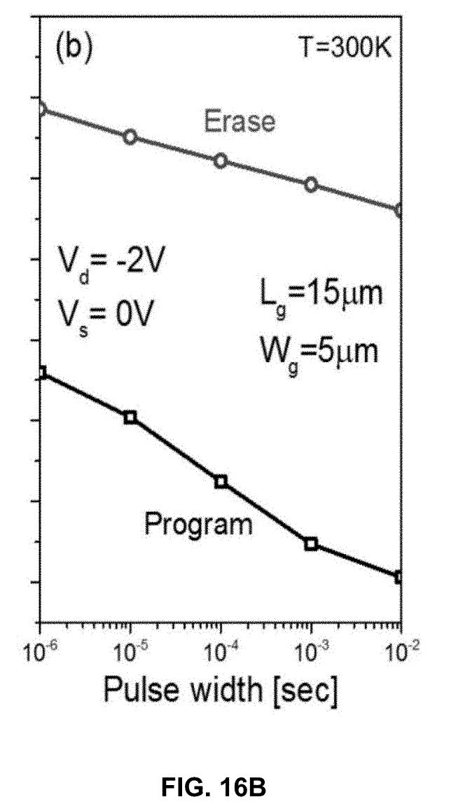

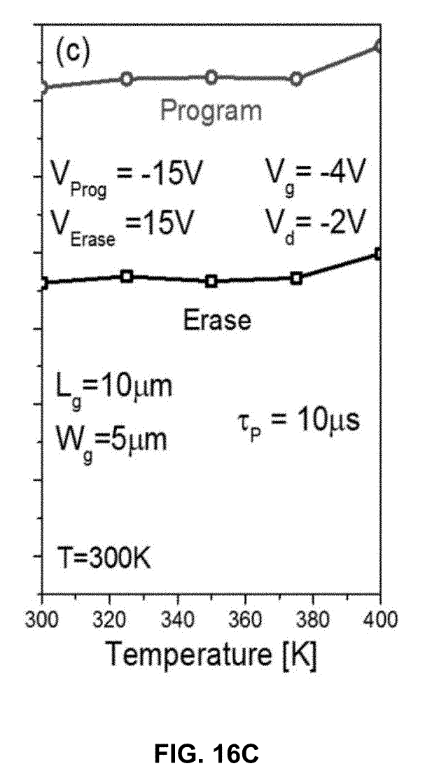

As shown in FIG. 12, the memory devices exhibit high level of endurance, with very stable memory window up to 10⁶ program/erase cycles. The one program-erase cycles includes alternating square wave pulses of −15V and +15V respectively, each pulse being 10 μs in duration. FIG. 13 shows increasing trend in ΔV_{T} with programing pulse duration. As the programming pulse width gets wider, charges have more time to tunnel through the tunneling oxide and get trapped in the HfO₂ trapping layer causing the shift in V_{T} getting larger. FIG. 14 shows temperature dependence of the hysteresis for a gate voltage sweep of in the range between −15V to +10V. The memory hysteresis curves in FIG. 15 shows two trends. First, it can be seen that the threshold voltage hysteresis and ON current (I_{ON}) shows significant increase with temperature. The increasing I_{ON} can be attributed to band gap reduction that occurs at elevated temperatures. Increase in hysteresis from 77K to room temperature can be attributed to the frozen traps getting activated as the temperature increases and becomes stable from room temperature till 400K when almost all traps have been activated and thus show less dependence on temperature increase. Second, the NVM TFET shows remarkable stability at high temperatures (300K-400K) with ΔV_{T} showing very little change till 400K. This is the unique characteristics of Tunnel FET transistors. The charge transport depends upon the band gap of the Silicon and band gaps have very weak dependence on temperature, as shown in reference [14] thus affecting the transfer characteristics very marginally. FIGS. 16A to 16C shows the V_{T} shift for a number of pulses (see FIG. 16A), programming pulse width (see FIG. 16B), and temperature (see FIG. 16C).

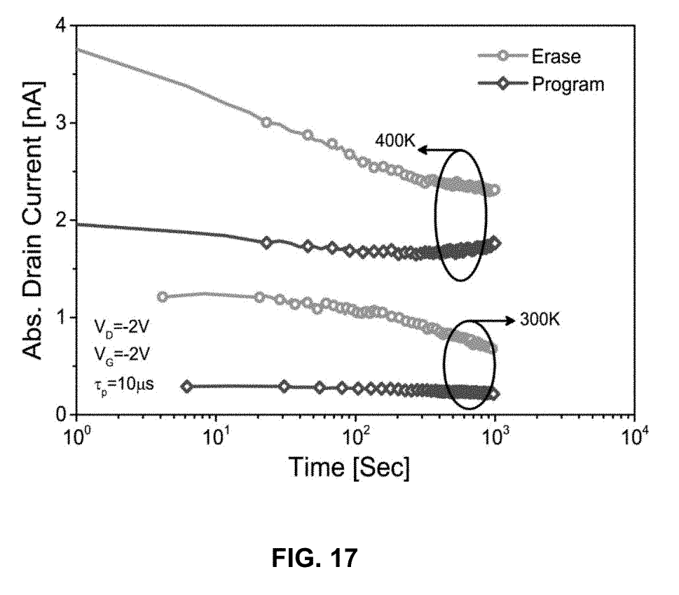

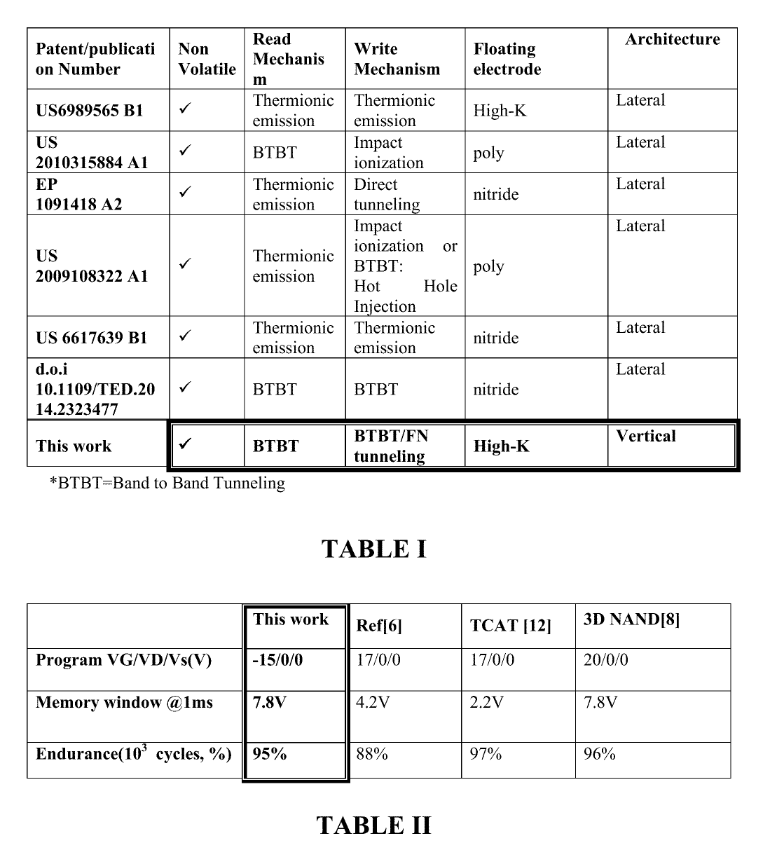

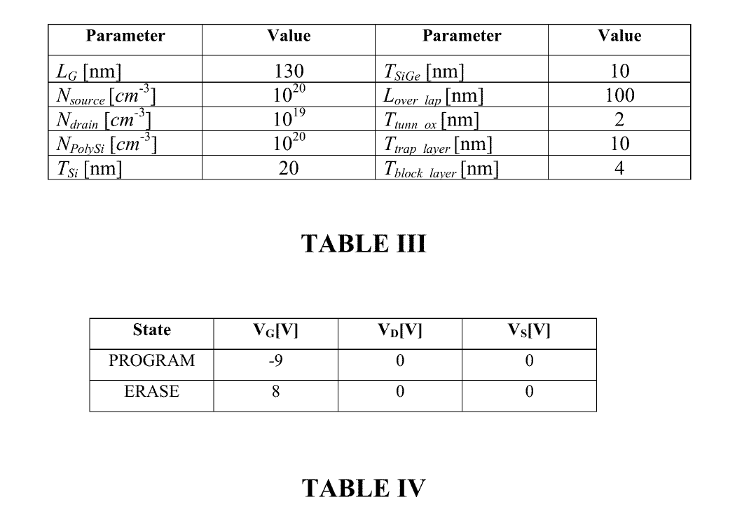

Regarding the retention characteristics, FIG. 17 shows the memory retention characteristics till 10³ secs for the devices fabricated at room temperature and at 400K, showing stable memory window even at elevated temperatures. The observed reduction from initial value of the memory window over time can be attributed to poor Al₂O₃/Silicon interface quality, which can be remedied by an ALD SiO₂ to reduce trap assisted leakage. Using SiO₂ as tunneling oxide will improve retention characteristics due to better interface quality with silicon substrate.

In sum, the main advantages of proposed Tunnel FET based non-volatile memory include the following features: (1) Being a Tunnel FET based memory, the transfer characteristics of the memory transistor does not directly depend on temperature and less sensitive over wide range of temperatures as compared to the MOSFET based nonvolatile memories. (2) The gate-source overlap architecture of the device offers superior carrier generation and charge injection into the gate stack at a given voltage as compared to MOSFETs, thus enabling efficient memory operation. (3) The high-K gate stack offer better charge trapping and retention than silicon nitride below 4 nm of thickness. Thus high-K gate stack allows for more aggressive scaling for state of the art technology nodes. (4) High hysteresis, low voltage operation and temperature insensitivity allows for the proposed memory device to find application is demanding operating environment. A brief overview of different parameters is given by Table II, to compare with the devices of reference [6], [8], and [12]. Moreover, Table I provides for a brief overview a summary of relevant patents and publications of non-volatile memory devices.

A nonvolatile memory device based on Tunnel FET that can operate at comparatively lower voltages and has stable memory operation up to 125° C. and program/erase cycles greater than 10⁶ has been shown. The device and its method of operation can help promote a more durable, efficient and robust nonvolatile memory function as a replacement for current Flash based solutions for military grade specifications.

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments, and be given the broadest reasonable interpretation in accordance with the language of the appended claims.

### REFERENCES

[1] L. De Michielis, L. Lattanzio, P. Palestri, L. Selmi, and A. M. Ionescu, “Tunnel-FET architecture with improved performance due to enhanced gate modulation of the tunneling barrier,” in 69th Device Research Conference., pp. 111-112, IEEE, June 2011.
[2] A. M. Ionescu and H. Riel, “Tunnel field-effect transistors as energy efficient electronic switches,” Nature, vol. 479, pp. 329-337, November 2011.
[3] Kristen E. Moselund et. Al, “InAs-Si Nanowire Heterojunction Tunnel FETs” Electron Device Society, IEEE Electron Device Letters, Vol. 33, October 2012.
[4] Mayer, F., Le Royer, C., Damlencourt, J. F., Romanjek, K., Andrieu, F., Tabone, C., Deleonibus, S., “Impact of SOI, Sil-xGexOI and GeOI substrates on CMOS compatible tunnel FET performance.” In Technical Digest—IEDM (Vol. 4, pp. 1-5). IEEE 2008.
[5] Chun Zhao, Ce Zhou Zhao, Stephen Taylor, Paul R. Chalker. “Review on Non-Volatile Memory with High-k Dielectrics: Flash for Generation Beyond 32 nm.” Materials 2014, 7, 5117-5145.
[6] Yi-Ruei Jhan, Yung-Chun Wu, Hsin-Yi Lin, Min-Feng Hung, Yu-Hsiang Chen, Mu-Shih Yeh, “High Performance of Fin-Shaped Tunnel Field-Effect Transistor SONOS Nonvolatile Memory with All Programming Mechanisms in Single Device.”, in IEEE TED, vol.61, no.7, July 2014.
[7] A. Biswas, “Tunnel Field Effect Transistors: from Steep-Slope Electronic Switches to Energy Efficient Logic Applications.” Doctoral Dissertation No. 6802, Ecole Polytechnique Fédérale de Lausanne (EPFL), Lausanne, Oct. 9, 2015.
[8] A. Biswas, S. Tomar, E. A. Casu, A. M. Ionescu “Vertical band-to-band tunneling based Non-Volatile Memory with high-K gate stack and stable hysteresis characteristics up to 400K” 74th Device Research Conference, IEEE June 2016.
[9] A. Biswas, S. Tomar, A. M. Ionescu, “Vertical Tunnel FET Non-Volatile Memory with Al₂O₃/HfO₂/Al₂O₃ gate stack” IEEE Silicon Nanoelectronics Workshop June 2016.
[10] A. Biswas, C. Alper, L. De Michielis, and A. M. Ionescu, “New tunnel-FET architecture with enhanced I ON and improved Miller Effect for energy efficient switching,” in Device Res. Conf.—Conf. Dig. DRC, pp. 131-132, IEEE, June 2012.
[11] You, H.-W.; Cho, W.-J. “Charge trapping properties of the HfO₂ layer with various thicknesses for charge trap flash memory applications.” Appl. Phys. Lett. 2010, 96, 093506:1-093506:3.
[12] J. Jang et al., “Vertical cell array using TCAT (terabit cell array for ultra-high density transistor) technology for ultra-high density NAND flash memory,” in Proc. Symposium Very Large Scale Integration (VLSI) Technology June 2009, pp. 192-193.
[13] H.-T. Lue et al., “A highly scalable 8-layer 3D vertical-gate (VG) TFT NAND flash using junction-free buried channel BE-SONOS device,” in Proc. Symposium Very Large Scale Integration (VLSI) Technology., June 2010, pp. 131-132.
[14] Mookerjea, S., Mohata, D., Mayer, T., Narayanan, V. & Datta, S. “Temperature-dependent I-V characteristics of a vertical In_{0.53}Ga_{0.47}As tunnel FET.” IEEE Electron Device Lett. 31,564-566 (2010).

1. A tunnel field effect transistor, comprising:
a source region, a gate region, a channel region, and a drain region, the gate region including a gate stack,
wherein an area of the source region that is facing the channel region is overlapped by the gate stack.

2. The tunnel field effect transistor according to claim 1, wherein the gate stack includes a first SiO₂ layer, a Si₃N₄ layer, and a second SiO₂ layer.

3. The tunnel field effect transistor according to claim 1, wherein the gate stack includes a first Al₂O₃ layer, a HfO₂ layer, and a second Al₂O₃ layer.

4. The tunnel field effect transistor according to claim 1, further comprising:
a low bandgap SiGe epitaxial layer arranged between the source region and the gate stack, in the overlapped area and in an intrinsic silicon area.

5. The tunnel field effect transistor according to claim 1, wherein an upper surface of the channel region is at least partially covered by the gate stack.

6. The tunnel field effect transistor according to claim 1, operated as a non-volatile memory device.

7. A method for operating a tunnel field effect transistor in a non-volatile memory device, the tunnel field effect transistor including a source region, a gate region, a channel region, a drain region, and a substrate, the gate region including a gate stack, wherein an area of the source region that is facing the channel region is overlapped by the gate stack, the method comprising the steps of:
performing a write operation;
performing a read operation; and
performing an erase operation

8. The method according to claim 7, wherein the write operation includes a step of applying a negative voltage pulse to the gate region while the drain region, the source region, and the substrate are grounded.

9. The method according to claim 7, wherein the read operation includes a step of applying a negative bias to the gate region and a negative voltage to the drain region, while the source region and the substrate are grounded.

10. The method according to claim 7, wherein the erase operation includes a step of applying a positive voltage pulse to the gate region while the drain region, the source region, and the substrate are grounded.

11. A method for operating a tunnel field effect transistor in a non-volatile memory device, the tunnel field effect transistor including a source region, a gate region, a channel region, a drain region, and a substrate, the gate region including a gate stack, wherein an area of the source region that is facing the channel region is overlapped by the gate stack, the method comprising the step of:
operating the tunnel field effect transistor using vertical band-to-band tunneling to augment charge trapping in the gate stack.
